(19) United States
(12) Patent Application Publication
(10) Pub. No.: US 2012/0056765 A1
(43) Pub. Date: Mar. 8, 2012

(54) METHOD FOR CONTROLLING THE LOOP DELAY IN A SIGMA-DELTA MODULATOR, AND SIGMA-DELTA MODULATOR IMPLEMENTING SAID METHOD

(75) Inventor: Jean-Michel Hode, Saint-Cloud (FR)

(73) Assignee: THALES, NEUILLY SUR SEINE (FR)

(21) Appl. No.: 13/127,040

(22) PCT Filed: Oct. 29, 2009
(86) PCT No.: PCT/EP09/64321

§ 371 Date: Oct. 3, 2011

(30) Foreign Application Priority Data
Oct. 31, 2008 (FR) 08/06078

(51) Int. Cl. H03M 3/02; H03L 7/06

(52) U.S. Cl. 341/110; 327/149

(57) ABSTRACT

In a method for controlling the loop delay in a sigma-delta modulator having a loop including an integrator, an analog-to-digital converter, a digital-to-analog converter, and an adder-subtractor, at least one phase-control programmable digital command representing a phase shift is applied to one of the clock signals of the converters of the loop to adjust the relative phase between a clock signal of the analog-to-digital converter and a clock signal of the digital-to-analog converter. A sigma-delta modulator for converting an analog signal implements the method.

The present invention relates to a method for controlling the loop delay in a sigma-delta modulator and a modulator implementing the method. It applies notably to the field of electronics.

The conversion of an analog signal into a digital signal has become a conventional operation in present-day electronic circuits, by virtue of standard commercially available components generally grouped together under the acronym ADC, for “Analog-to-Digital Converter”. A signal e(t) is represented, varying continuously in time and able to take any value in a form s(t) sampled in time. Each sample can take a finite number of possible quantized values and each value is encoded on a well defined number of bits. Each bit can take only two possible values, 1 or 0 for example.

Conventional ADCs provide precision levels that are satisfactory at relatively low input signal frequencies, of the order of a few tens or even hundreds of megahertz. This means that at these frequencies, the difference between the signal represented digitally at the output and the analog input signal is acceptable. But in the field of microwave frequencies, when the frequency of the input signal is of the order of a few gigahertz, the dynamics of conventional ADCs, i.e. their capability to sample/quantize the input signal both rapidly and accurately turns out to be markedly inadequate. First of all, this is due to the inadequate rise time of an internal component of ADCs called the sample/hold circuit. It may be difficult for a sample/hold circuit to stabilize an input signal with a view to quantizing it if it is at too high a frequency, the duration required for this stabilization hence being too long with respect to the sampling period. This introduces errors, i.e. digital samples can be unrepresentative of the analog signal. Each sample can then be encoded only on a reduced number of amplitude values. This intrinsically generates an error due to the lack of precision before the quantization of the amplitude of each sample. Consequently, the error inherent to the digitization method of a conventional ADC at high sampling frequency is the sum of the error described, related to the rapidity defect of the sample/hold circuit, and of the quantization rounding error which reflects the difference between the signal thus sampled/held and its quantized digital representation. This overall error is incorrectly referred to as “quantization noise” since, in practice, the part related to the quantization is in the majority (at least at low frequency). Thus, at high frequency, the difference between the signal represented digitally at the output and the analog signal at the input becomes non-negligible and the precision of the ADC is no longer satisfactory. In summary, the precision of conventional ADCs decreases when the frequency of the analog signal e(t) applied at their input increases. They are therefore not suitable for use in very high-frequency applications demanding good digital precision, such as radars for example.

A method called sigma-delta modulation allows to improve the precision of an ADC locally around a frequency, if necessary around a high frequency. The basic principle is to make the digital output signal vary arbitrarily, or to “modulate” it, so as to minimize the error for any spectral component contained in the relevant band (which depends on the use), even if it means that samples of the digital output signal can appear unrepresentative of the analog input signal. To this end, sigma-delta modulation requires by principle that the signal be strongly oversampled, which can be done only on a small number of bits. This amounts to improving the time-domain precision by cutting the signal into a large number of samples but, as explained earlier, at the cost of a reduction in amplitude precision due to the increase in sampling frequency. However, by relying on oversampling, the digital output signal can be modulated in order to minimize the power of this quantization noise in a defined frequency band.

In the frequency or spectral domain, it is commonly said that sigma-delta modulation makes the quantization noise “compliant”. Specifically, the modulation of the digital output signal, which is adapted to the frequency of the input signal, amounts to minimizing the spectral density of the quantization noise around the frequency of the useful signal. In fact, the spectrum of the quantization noise must be made “compliant” with an ideal spectrum presenting a trough near the frequency of use. Thus, even if an overall significant quantization noise is intrinsically generated in sigma-delta modulation, and this regardless of the frequency of the signal at the input, at least this quantization noise is of low power close to the frequency of use.

A sigma-delta modulator can be implemented from an ADC converter controlled conventionally in a feedback loop, with a view to lessening the effect of its quantization noise on its digital output. In this case, a digital-to-analog converter, hereafter referred to as a DAC converter, provides for converting the digital output signal from the ADC converter back to analog with a view to subtracting it from the input signal, through the principle of closed loop control. An amplifier and a loop filter are used to circumvent the drawback of conventional ADCs by combining high frequency and fine resolution.

During the design of such a modulator, it is important to take into account the times required to perform the two conversions set up in the loop. Specifically, if the designer wishes to prevent making the loop unstable, it is not possible to choose any random values for the loop gain. The loop must meet the Nyquist criterion which imposes a restriction as regards variations in the complex gain of the loop around and near the point -. For given converters, the stability of the loop is therefore determined by the choice of the filter and of the gain of the integration operation.

The loop delay is a fundamental parameter for sigma-delta modulators since it directly affects their stability by the variation in phase that it induces in the band, thereby reducing the phase stability margin, i.e. the variation in phase that the loop tolerates without making the modulator unstable.

For a bandpass modulator, this loop delay also contributes to the average value in the band by introducing an overall offset of the phase response. It is therefore crucial to be able to compensate for this average offset of the phase response in order to recenter it around zero in the band to optimize the phase stability margin.

The compensation of this average offset is usually carried out at the moment of the initial adjustment of the modulator. It is also possible to manually adjust this offset during maintenance interventions. Between two interventions, the average offset value can vary while the modulator is being used, for example due to temperature variations and component ageing. This has the consequence of limiting the operating range and therefore of requiring a sub-optimal use of the modulator.

One aim of the invention is notably to overcome the abovementioned drawbacks.

To this end, the invention relates to a method for controlling the loop delay in a sigma-delta modulator composed of a loop including at least an integrator, an analog-to-digital converter ADC, a digital-to-analog converter DAC and an adder-subtractor. At least one phase-control programmable digital command representing a phase shift is applied to one of the clock signals of the converters of the loop in order to adjust the relative phase between the clock signal h₁(t) of the ADC converter and the clock signal h₂(t) of the DAC converter.

The clock signal h₁(t) of the ADC converter and the clock signal h₂(t) of the DAC converter of the sigma-delta modulator are generated, for example, from a reference signal r(t) of frequency f_{REF} used as frequency and phase reference.

According to one aspect of the invention, a phase-control programmable digital command φ₁ provides for adjusting the phase of the clock signal h₁(t) of the ADC converter relative to the phase of the reference signal r(t). The phase of the clock signal h₁(t) is adjusted, for example, by a digital phase offset mechanism. The phase of the clock signal h₁(t) can also be adjusted by a phase-lock loop.

According to another aspect of the invention, a phase-control programmable digital command φ₂ provides for adjusting the phase of the clock signal h₂(t) of the DAC converter relative to the phase of the reference signal r(t). The phase of the clock signal h₂(t) is adjusted, for example, by a digital phase offset mechanism. The phase of the clock signal h₂(t) can also be adjusted by a phase-lock loop.

According to another aspect of the invention, the reference signal r(t) is, for example, used as the clock signal h₂(t) for the DAC converter.

According to another aspect of the invention, the reference signal r(t) is used as the clock signal h₁(t) for the ADC converter.

The invention also relates to a sigma-delta modulator for converting an analog signal into a digital signal, said modulator, composed of at least an integrator, an analog-to-digital converter ADC, a digital-to-analog converter DAC and an adder-subtractor, implementing the method according to one of the preceding claims and including means for adjusting the phase of at least one of the clock signals of the ADC and DAC converters of the modulator by at least one phase-control programmable digital command.

The invention notably has the advantage of allowing an automatic control, i.e. without human intervention, of the loop delay in a sigma-delta modulator.

Other features and advantages of the invention will become apparent from the following description given by way of illustration and in a non-limiting manner, with reference to the accompanying drawings in which:

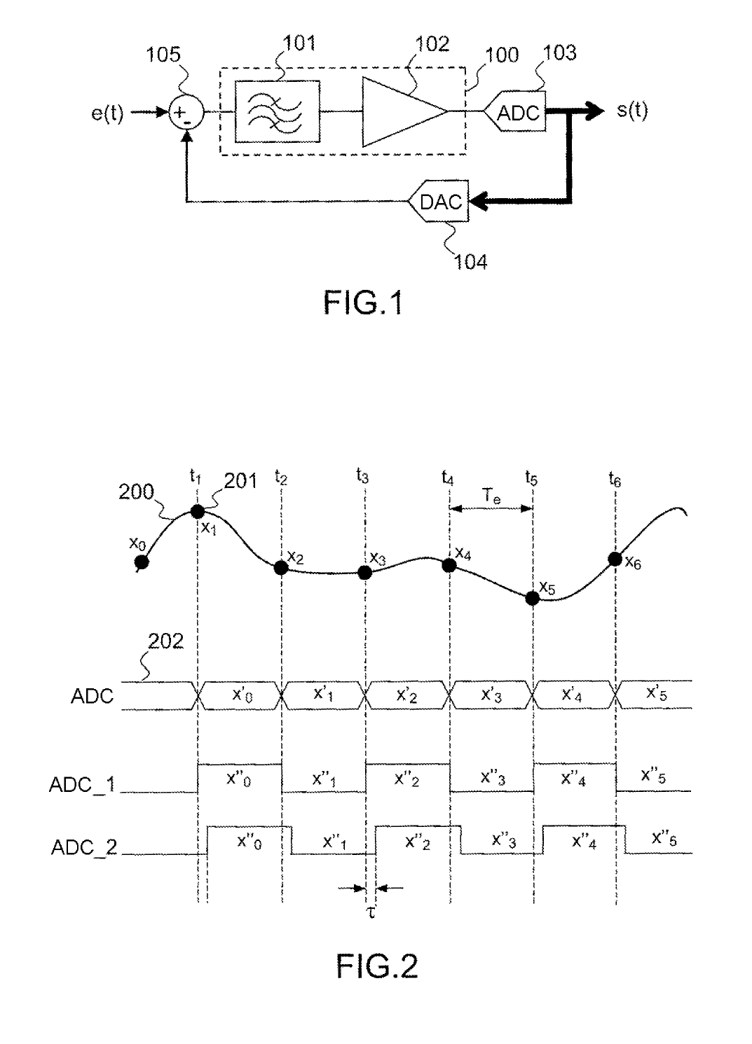

FIG. 1 presents an example continuous-time sigma-delta modulator

FIG. 2 illustrates the time sequencing of operations of the ADC and DAC converters of a sigma-delta modulator, and the principle of the method according to the invention;

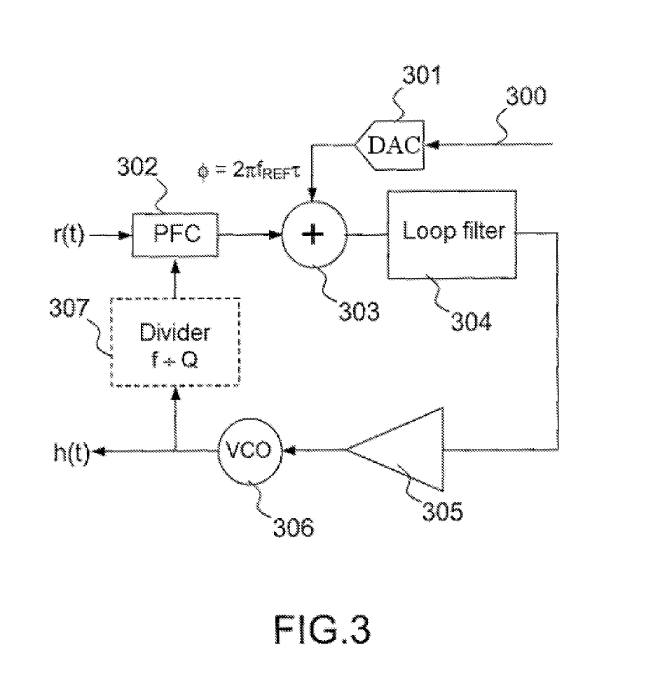

FIG. 3 gives an example phase-lock loop;

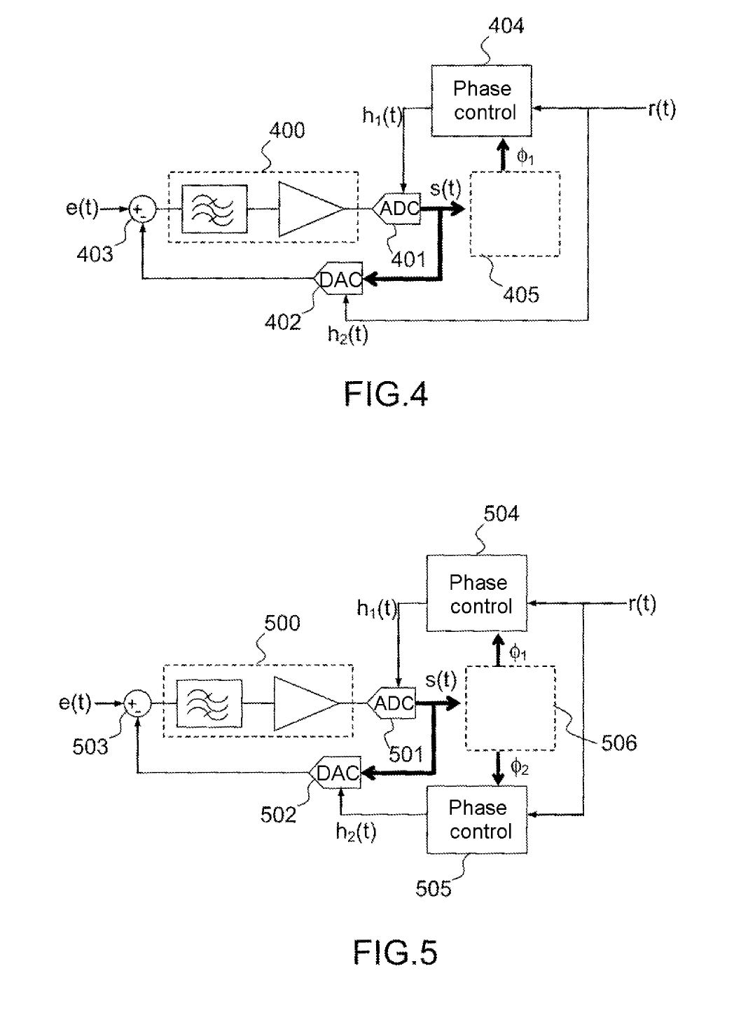

FIG. 4 presents a first variant of a sigma-delta modulator implementing the method according to the invention;

FIG. 5 presents a second variant of a sigma-delta modulator implementing the method according to the invention.

FIG. 1 presents an example sigma-delta modulator. As explained previously, the role of a continuous-time sigma-delta modulator is two-fold. A first role is to sample and digitize at high sampling frequency an analog signal e(t) with a small number of bits, i.e. less than the theoretical number required to reach a given signal-to-noise ratio. A second role is to shape the quantization noise so that the spectral density of this noise in the useful band of the signal to be converted is compatible with the signal-to-noise ratio aimed at after decimation. To this end, a continuous-time bandpass sigma-delta modulator is comparable to a feedback loop. An integrator 100 itself composed of a bandpass filter 101 and an amplifier 102 has the role of integrating and amplifying the error in the useful band of the signal. The loop comprises an ADC converter 103 producing the output s(t) of the modulator. The output s(t), i.e. the encoded signal, is then looped back to a DAC converter 104. An adder-subtractor 105 for evaluating the difference between the input signal and the encoded signal is placed at the input of the modulator. The signal is digital between the output of the ADC converter 103 and the input of the DAC converter 104.

FIG. 2 illustrates the time sequencing of operations of the ADC and DAC converters of a sigma-delta modulator, and the principle of the method according to the invention.

At the output of the integrator of the loop of the sigma-delta modulator, the signal is analog 200. The analog-to-digital conversion performed by the ADC of the loop comprises a sampling operation and a quantization operation. The samples 201 are produced at the rhythm Tₑ corresponding to the sampling period of the converter. In the example of the figure, a sequence of seven signal samples denoted by x₀ to x₆ are represented. The state of the output of the ADC converter is represented 202 taking into account the conversion delay. This conversion delay is for example equal to Tₑ. Thus, for the signal sample x₁ taken at the instant t₁, the quantized value x₁′ will be available at the output of the converter at the instant t₂=t₁+Tₑ. Thus, the digital values at the output of the ADC at the instants t₁, t₂, . . . , t₆ are x₀′, x₁′, . . . , x₅′ corresponding to the signal samples x₀, x₁, . . . , x₅ respectively.

The digital signal s(t) available at the output of the ADC converter is then reinjected into the loop. This signal is processed by a DAC converter. The delay due to the processing of the signal by the DAC is disregarded for the purposes of clarity of the description. In reality, this delay may be, for example, half of Tₑ, without calling into question the principle of the invention explained above. The output state of the DAC is illustrated in two cases denoted by DAC_1 and DAC_2.

The first case is the usual case. The output DAC_1 of the DAC converter is represented when the same clock signal is used by both converters, ADC and DAC. Since the digital-to-analog conversion delay is disregarded, the output of the DAC switches at the instant t₁, t₂, . . . , t₆ and takes the analog values x₀″, x₁″, . . . , x₅″ corresponding to the samples x₀, x₁, . . . , x₅ respectively.

The second case presents the output DAC_of the DAC converter when the ADC and DAC converters use separate clock signals of the same frequency fₑ1/Tₑ but out of phase with one another. In the example of FIG. , the output DAC_of the DAC converter will switch, for example, at the instants t₁+τ, t₂+τ, . . . , t₆+τ where τ is a time delay of the clock of the DAC with respect to the clock of the ADC. The method according to the invention proposes digitally controlling the value of this delay so as to adjust the overall delay of the loop. To make the value of τ vary in time, a phase-control programmable digital command φ corresponding to a phase shift of the clock signal is calculated, φ being related to the delay τ by the relationship:

φ=2πfₑτ (1)

The example of FIG. 2 shows that only the clock of the DAC is adjusted, but it is also possible to adjust the clock of the ADC and keep the clock of the DAC fixed, or adjust both clocks of both converters simultaneously.

According to one embodiment, the variation in phase is performed by a digital phase offset mechanism, called a “phase shifter”. The benefit of this type of device is that it does not significantly degrade the spectral purity of the signals to be phase-shifted and that it is available in the form of very compact components able to operate in a wide band at very high frequency. According to another embodiment, the variation in phase is performed by a phase-lock loop, the phase of which can be translated by injecting a continuous signal delivered by a DAC converter. The benefit of this type of device is that it presents a large number of phase states owing to an almost continuous control of the phase.

FIG. 3 gives an example phase-lock loop known to a person skilled in the art and allowing the phase of the clock signal of the ADC or DAC of the sigma-delta modulator to be adjusted, taking into account a phase-control digital command presented at its input. Such a phase-lock loop relies notably on a reference signal r(t) of frequency f_{REF} used as frequency and phase reference for generating the clock signals and, without detriment to the general aspects of the description, able to be expressed according to the following equation:

r(t)=cos(2πf_{REF}t) (2)

A phase/frequency comparator PFC 302 generates an output signal being on average proportional to the phase error between the output signal h(t) of the loop, i.e. the signal used as the clock for the ADC or DAC of the sigma-delta modulator, and the reference signal r(t). A phase-control digital command 300 is injected into a DAC converter 301 so as to add 303 a continuous voltage on the error signal from the comparator 302 in order to control the phase difference between the output signal h(t) and the input signal r(t). A loop filter 304 is used to limit the band of the signal following the addition 303 of said continuous voltage. The output of the loop filter is directed to an amplifier 305 for adjusting the gain of the phase-lock loop. The signal thus filtered and amplified is used to control a voltage-controlled oscillator (VCO) 306, said oscillator synthesizing the output signal h(t) of the phase-lock loop:

h(t)=cos((2πf_{REF}(t+τ)) (3)

Optionally, a frequency divider 307 can be placed in the loop so as to divide by a factor Q the frequency at the output of the VCO 306. The phase-lock loop can hence operate with a reference signal r(t) of frequency Q times less than the output signal h(t). The signal h(t) will be expressed in this case:

h(t)=cos((2πQf_{REF}(t+τ)) (4)

In this case, the clock signal thus generated will vary at the frequency Q×f_{REF} and the phase/frequency comparator 302 will supply as output a signal proportional to the average of the phase error between the output signal h(t) divided in frequency by the factor Q and the reference signal r(t) and of frequency Q times lower than h(t).

FIG. 4 presents a first variant of a sigma-delta modulator implementing the method according to the invention. The main items composing a conventional sigma-delta modulator as described with the aid of FIG. 1 are used, i.e. an integrator 400, an ADC converter 401, a DAC converter 402 and an adder-subtractor 403. The loop takes at the input of the adder-subtractor 403 the signal e(t) to be modulated. The output of the loop corresponds to the signal s(t) available at the output of the ADC converter 401. According to the invention, the overall delay of the loop of the modulator is controlled by adjusting the relative phase between the clock signals h₁(t) and h₂(t) of the two converters 401, 402. To this end, a reference signal r(t), for example a sinusoid of frequency f_{REF} equal to the sampling frequency of the loop, i.e. f_{REF}=fₑ, is used as the basis for the generation of the clock signals h₁(t) and h₂(t). The signal r(t) is directly used as the clock for the DAC converter , i.e. h₂(t) =r(t). The relative phase between the two clocks is controlled by adjusting the phase of the clock signal h₁(t). A calculation module 405 deduces from the output s(t) of the modulator a digital phase-control command value φ₁. The calculation module 405 can, for example, be an FPGA type programmable logic device, an ASIC circuit, or a DSP type processor. A digital phase-control device 404 according to one or other of the embodiments described takes at its input a programmable digital command φ in order to adjust the phase of the signal h₁(t) relative to the phase of the signal r(t), the signal r(t) also being presented at the input of the phase-lock loop.

It is also possible, in another variant, to use the signal r(t) as the clock of the ADC, i.e. h₁(t)=r(t), and to adjust h₂(t) by virtue of a phase-lock loop.

The sigma-delta modulator comprising this clock control mechanism thus provides for adjusting the overall delay of the sigma-delta modulator.

FIG. 5 presents a second variant of a sigma-delta modulator implementing the method according to the invention. As for the variant of FIG. 4, the main items composing a conventional sigma-delta modulator are used, i.e. an integrator 500, an ADC converter 501, a DAC converter 502 and an adder-subtractor 503.

The calculation module 506 deduces from the output s(t) of the modulator two phase-control programmable digital command values φ₁ and φ₂. These commands are used, respectively, by two digital phase-control devices 504, 505 allowing the phase of the clock signals h₁(t) and h₂(t) to be adjusted. Thus, the overall delay of the loop of the modulator is controlled by adjusting the relative phase between the clock signals h₁(t) and h₂(t) of the two converters 501, 502.

1. A method for controlling a loop delay in a sigma-delta modulator having a loop including an integrator an analog-to-digital converter, a digital-to-analog converter, and an adder-subtractor, said method comprising applying at least one phase-control programmable digital command representing a phase shift to one of the clock signals of the converters of the loop to adjust the relative phase between a clock signal of the analog-to-digital converter and a clock signal of the digital-to-analog converter.

2. The method as claimed in claim 1, wherein the clock signal of the analog-to-digital converter and the clock signal of the digital-to-analog converter of the sigma-delta modulator are generated from a reference signal of frequency used as frequency and phase reference.

3. The method according to claim 1, wherein a phase-control programmable digital command provides for adjusting the phase of the clock signal of the analog-to-digital converter relative to the phase of the reference signal.

4. The method as claimed in claim 3, wherein the phase of the clock signal of the analog-to-digital converter is adjusted by a digital phase offset mechanism.

5. The method as claimed in claim 3, wherein the phase of the clock signal of the analog-to-digital converter is adjusted by a phase-lock loop.

6. The method as claimed in claim 2, wherein a phase-control programmable digital command provides for adjusting the phase of the clock signal of the digital-to-analog converter relative to the phase of the reference signal.

7. The method as claimed in claim 6, wherein the phase of the clock signal of the digital-to-analog converter is adjusted by a digital phase offset mechanism.

8. The method as claimed in claim 6, wherein the phase of the clock signal of the digital-to-analog converter is adjusted by a phase-lock loop.

9. The method as claimed in claim 2, wherein the reference signal is used as the clock signal of the digital-to-analog converter.

10. The method as claimed in claim 1, wherein the reference signal is used as the clock signal of the analog-to-digital converter.

11. A sigma-delta modulator for converting an analog signal into a digital signal composed of at least, said sigma-delta modulator comprising:
an integrator;
an analog-to-digital converter;
a digital-to-analog converter; and
an adder-subtractor, said modulator implementing the method as claimed in claim 1 and further comprising means for adjusting the phase of at least one of the clock signals of the analog-to-digital converter and the digital-to-analog converter of the modulator by at least one phase-control programmable digital command.
